(19) United States
(12) Patent Application Publication
(10) Pub. No.: US 2014/0167223 A1
(43) Pub. Date: Jun. 19, 2014

(54) Semiconductor Cooling Device

(71) Applicant: INTERMOLECULAR, INC., San Jose, CA (US)

(72) Inventor: Tony W. Firth, San Jose, CA (US)

(73) Assignee: INTERMOLECULAR, INC., San Jose, CA (US)

(21) Appl. No.: 13/717,528

(22) Filed: Dec. 17, 2012

(51) Int. Cl. H01L 23/34; H01L 21/77; H01L 29/16

(52) U.S. Cl. CPC H01L 23/34; H01L 29/16; H01L 21/77
USPC 257/616; 257/734; 257/713; 438/107

(57) ABSTRACT

A system and a method of self-cooling a semiconductor package are described. A cell is formed, which contains a thermally conductive and electrically insulative material, sandwiched between a first thermally conductive plate and a second thermally conductive plate. A plurality of integrated circuits are formed by combinatorial processing. The plurality of integrated circuits are interconnected into a semiconductor integrated circuit package. The cell is thermally bonded to the semiconductor integrated circuit package. The first thermally conductive plate is electrically connected to the semiconductor integrated circuit package. A current is supplied to the second thermally conductive plate by an electrical lead from a supply voltage. Power is provided in series to the semiconductor integrated circuit package and through the cell.

### BACKGROUND

Removing heat from a semiconductor device is vital to keeping the device operating properly and to avoid premature failure of the device. The amount of heat produced by a device tends to be directly proportional to the amount of power consumed. Therefore, a large-powered device will produce a large amount of heat, which needs to be removed from the device in order to prevent device failure.

A heat sink is designed to remove heat from a device. A heat sink is made of thermally conductive material and is thermally bonded to the device. It may have a finned contour to increase surface area, which increases heat removal from the device. However, a heat sink needs to be relatively large to remove a significant amount of heat. Additional mechanisms or devices can be added to assist in heat removal, but those additional mechanisms or devices require a power source, which also adds to the production of heat.

It is within this context that the embodiments arise.

### SUMMARY

In some embodiments, a self-cooling semiconductor device is described. A semiconductor substrate contains a plurality of transistors. A first electrically conductive plate is coupled to the semiconductor substrate. A semiconductor material is located between the first electrically conductive plate and a second electrically conductive plate. A first electrical lead from the first electrically conductive plate is coupled to a semiconductor junction of the semiconductor substrate. A second electrical lead from the second electrically conductive plate is coupled to a supply voltage. The first electrical lead and the second electrical lead are coupled in series.

In some embodiments, a self-cooling semiconductor package is described. An integrated circuit is incorporated into the semiconductor package. A first electrically conductive plate is thermally bonded to the semiconductor circuit package. A semiconductor material is adjacent to the first electrically conductive plate. A second electrically conductive plate is adjacent to the semiconductor material. A supply voltage is provided to the second electrically conductive plate. An electrical lead is coupled from the first electrically conductive plate to the integrated circuit. The supply voltage and the electrical lead are coupled in series.

In some embodiments, a method of self-cooling a semiconductor package is described. The method initiates with coupling a thermal gradient cell to an integrated circuit of the semiconductor package. The method includes supplying a voltage to the thermal gradient cell and powering the integrated circuit with the voltage from the thermal gradient cell.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a schematic diagram, which illustrates an implementation of combinatorial processing and evaluation according to embodiments of the invention;

FIG. 2 is a schematic diagram illustrating a general methodology for combinatorial process sequence integration according to embodiments of the invention;

FIG. 3 is a block diagram illustrating a semiconductor package according to embodiments of the invention; and

FIG. 4 is a flowchart for a method of self-cooling a semiconductor package according to embodiments of the invention.

### DETAILED DESCRIPTION

Semiconductor manufacturing may include a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization, and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices, such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing, such as etching and cleaning. HPC processing techniques have also been successfully adapted to deposition processes, such as physical vapor deposition (PVD), atomic layer deposition (ALD), and chemical vapor deposition (CVD).

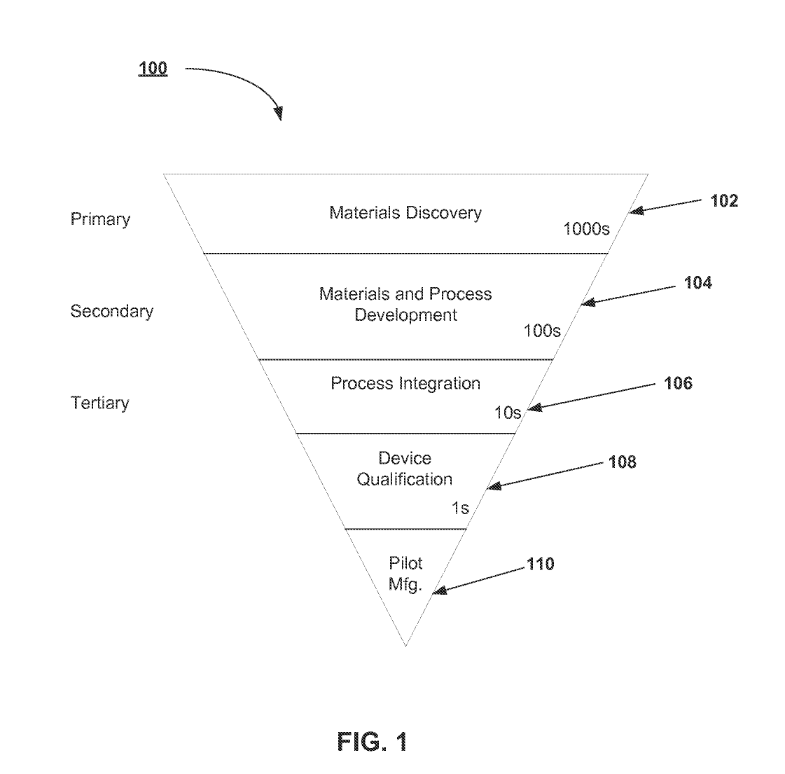

FIG. 1 is a schematic diagram 100, which illustrates an implementation of combinatorial processing and evaluation using primary, secondary, and tertiary screening. The schematic diagram 100 illustrates the relative number of combinatorial processes that run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage, performed using primary screening techniques. Primary screening techniques may include dividing substrates into coupons and depositing materials using varied processes. The materials are then evaluated and promising candidates are advanced to the secondary screen, such as a materials and process development stage 104. Evaluation of the materials is performed using metrology tools such as electronic testers and imaging tools, e.g. microscopes.

The materials and process development stage 104 may evaluate hundreds of materials (i.e., a magnitude smaller than the primary stage) and may focus on the processes used to deposit or develop those materials. Promising materials and processes are again selected and advanced to the tertiary screen, such as a process integration stage 106, where tens of materials and/or processes and combinations are evaluated. The tertiary screen or process integration stage 106 may focus on integrating the selected processes and materials with other processes and materials.

The most promising materials and processes from the tertiary screen are advanced to device qualification stage 108. In device qualification stage 108, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing stage 110.

The schematic diagram 100 is an example of various techniques that may be used to evaluate and select materials and processes for the development of new materials and processes. The descriptions of primary, secondary, etc. screening and the various stages, 102-110 are arbitrary and the stages may overlap, occur out of sequence, or be described and performed in many other ways.

The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than just considering a series of local optimums, i.e., where the best conditions and materials for each manufacturing unit operation is considered in isolation, the embodiments described herein consider interaction effects introduced due to the multitude of processing operations that are performed and the order in which such multitude of processing operations are performed when fabricating a device. A global optimum sequence order is therefore derived and as part of this derivation, the unit processes, unit process parameters, and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate, which are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants, and location of structures within each region are designed to enable valid statistical analysis of the test results within each region and across regions to be performed.

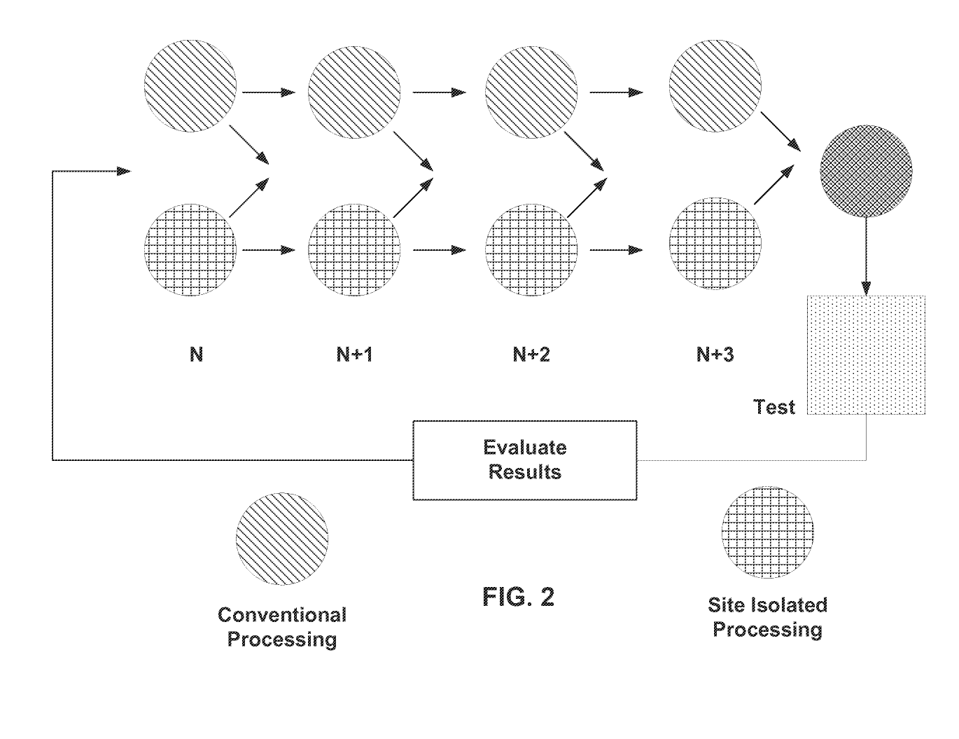

FIG. 2 is a simplified schematic diagram illustrating a general methodology for combinatorial process sequence integration that includes site isolated processing and/or conventional processing in accordance with an embodiment of the invention. The substrate is initially processed using conventional process N. In an exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed, such that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

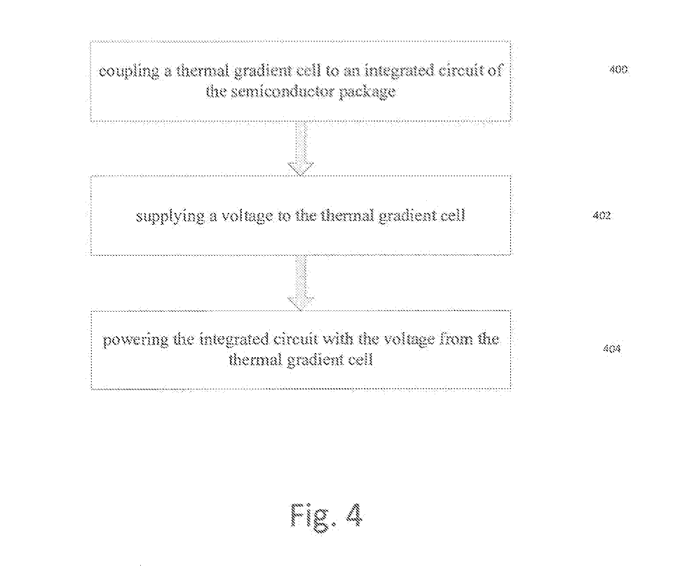

It should be appreciated that various other combinations of conventional and combinatorial processes can be included in the processing sequence with regard to FIG. 4. For instance, the combinatorial process sequence integration can be applied to any desired segments and/or portions of an overall process flow. Characterization, including physical, chemical, acoustic, magnetic, electrical, optical, etc. testing can be performed after each process operation and/or series of process operations within the process flow, as desired. The feedback provided by the testing is used to select certain materials, processes, process conditions, and process sequences and eliminate others. Furthermore, the above flows can be applied to entire monolithic substrates or portions of monolithic substrates, such as coupons.

Under combinatorial processing operations, the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and are not meant to be an exhaustive list, as other process parameters used in semiconductor manufacturing may be varied.

As mentioned above, within a region, the process conditions are substantially uniform, in contrast to gradient processing techniques which rely on the inherent non-uniformity of the material deposition. That is, the embodiments described herein may locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and therefore, non-overlapping. When the regions are adjacent, there may be a slight overlap wherein the materials or precise process interactions are not known; however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Semiconductor components formed by the above-described combinatorial processing may be interconnected to form a semiconductor device assembled in a semiconductor package. The semiconductor device produces heat during operation where the amount of heat produced is proportional to the amount of power consumed and the produced heat must be dissipated through the package. Accordingly, a high-powered semiconductor package requires removal of a larger amount of heat to keep the package functioning properly. A thermally conductive material may be attached to the semiconductor package for the removal of heat, via a thermally bonding material. The thermally conductive material may be a heat sink, formed of metal or other thermally conductive material. The exposed region of the heat sink may have a finned contour to increase the surface area, and thereby increase the rate or efficiency of heat removal. The embodiments below may be integrated with semiconductor devices formed through combinatorial processes as described with reference to FIGS. 1 and 2. However, this is not meant to be limiting as the embodiments may be incorporated with semiconductor devices or packages made from conventional processing techniques or a combination of conventional and combinatorial processing techniques. It should be appreciated that the semiconductor device or package may refer to microprocessors supplied from a few volts to industrial rectifiers supplied from up to a thousand volts.

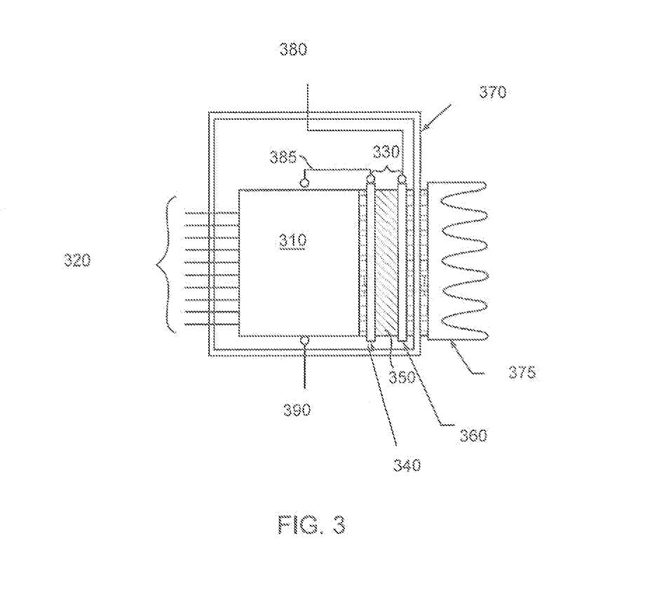

FIG. 3 is a block diagram illustrating a semiconductor device or semiconductor package 300 according to embodiments of the invention. Pluralities of transistors and/or integrated circuits are interconnected to form a semiconductor package 310. The plurality of transistors and/or integrated circuits may be formed according to combinatorial processing techniques, as described above with reference to FIGS. 1-2, conventional semiconductor processing techniques or some combination of conventional and combinatorial processing as mentioned above. The semiconductor package 310 may contain any number of transistors, ranging from a relatively small number of transistors to several million transistors. The semiconductor package 310 may require a few volts of supply power or up to one thousand of volts. It should be appreciated that semiconductor package 310 may be any suitable semiconductor chip, including switches, rectifiers, etc. It should be further appreciated that a proportionally larger amount of heat is produced where the supply voltage requirements are larger, and in turn more heat needs to be removed from the package.

A plurality of semiconductor component connections 320 interconnect the semiconductor package 310 to an external device or component, such as a printed circuit board, substrate, or another semiconductor package, to name just a few. The semiconductor component connections 320 may include several different configurations and types of connections, such as but not limited to, a wire grid array, a lead frame array, a ball grid array, a flip chip, etc. The number of semiconductor component connections 320 will vary with the number and type of integrated circuits within the semiconductor package 310.

FIG. 3 also illustrates a thermal gradient cell 330, thermally bonded to the semiconductor component package 310. The thermal gradient cell 330 includes a first electrically conductive plate 340, which is thermally bonded to the semiconductor package 310. A semiconductor material 350 lies adjacent to the first electrically conductive plate 340. A second electrically conductive plate 360 lies adjacent to the opposite side of the semiconductor material 350. The semiconductor material 350 is sandwiched between the first electrically conductive plate 340 and the second electrically conductive plate 360, thereby defining two junctions at the interface of plates 340 and 360 with semiconductor material 350. In some embodiments, the semiconductor package 310 and the thermal gradient cell 330 are enclosed in an outer case 370. A heat sink 375 is affixed to an outer surface of the outer case 370, as illustrated in FIG. 3. In some embodiments the heat sink 375 may be affixed to the back side of the thermal gradient cell 330, via any suitable thermal bonding material.

With continued reference to FIG. 3, a supply voltage is provided through connection 380 and provides a voltage and current from a voltage source to the second electrically conductive plate 360, through the semiconductor material 350, and to the first electrically conductive plate 340. It should be appreciated that the current associated with the voltage source is supplied in series from the first electrically conductive plate 340 to the semiconductor package 310, via an electrical lead 385. The electrical lead 385 provides power to semiconductor package 310 and consequently is coupled to a semiconductor junction of a transistor of an integrated circuit of the semiconductor package. Accordingly, the same current that is drawn by the semiconductor component package 310 also powers the thermal gradient cell 330, resulting in a self-cooling semiconductor package 300. A supply voltage return connection 390 is also illustrated in FIG. 3.

The above-described self-cooling semiconductor package 300 provides an additional heat-removing mechanism with no additional power source. Heat that is produced by the semiconductor component package 310 is conducted towards the first electrically conductive plate 340. Thermal gradient cell 330 transfers thermal energy, i.e., heat, from the first electrically conductive plate 340, through the semiconductor material 350, and to the second electrically conductive plate 360. The heat is transferred from the second electrically conductive plate 360 to the outer case 370, and to the heat sink 375. The self-cooling semiconductor package 300 provides two avenues of heat removal, i.e., the thermal gradient cell 330 and the heat sink 375, with no additional power source. The power source used to power the semiconductor component package 300 also powers the thermal gradient cell 330. In some embodiments, the first electrically conductive plate 340 is referred to as a cold plate and the second electrically conductive plate 360 is referred to as a hot plate. In some embodiments, the thermal gradient cell 330 may be referred to as a Peltier cell. Thermal gradient cell 330 is inserted between semiconductor package 310 and outer case 370. Thus, a supply voltage provided through lead 380 to plate 360 provides a current to semiconductor package 310 across the junctions of thermal gradient cell 330, while heat is transferred from plate 340 to plate 360 of the thermal gradient cell. As plate 360 is thermally bonded to heat sink 375 either directly or through outer case 370, the heat generated by semiconductor package 310 is eventually transferred to the heat sink. It should be appreciated that plates 360 and 340 may be any suitable electrically conductive material, such as a metal. In some embodiments, plates 340 and 360 may be different metals. In addition, plates 340 and 360 are thermally conductive as well as electrically conductive. Semiconductor material 350 may be any suitable semiconductor material including silicon, germanium, etc.

FIG. 4 is a flowchart for a method 400 of self-cooling a semiconductor package according to some embodiments. The method initiates with operation 400 where a thermal gradient cell is coupled to an integrated circuit of the semiconductor package. The thermal gradient cell is a Peltier cell in some embodiments, as described above with reference to FIG. 3. In some embodiments, the integrated circuit may be formed through combinatorial processing techniques, conventional processing techniques, and/or some combination of the two. In operation 402 a voltage is supplied to the thermal gradient cell. The voltage may range from a few volts to thousands of volts depending on the type of integrated circuit. The method then advances to operation 404 where the integrated circuit is powered with the voltage from the thermal gradient cell. Thus, the integrated circuit and the thermal gradient cell are powered through a single voltage source in the embodiments.

Heat is removed from the semiconductor package to the environment via a heat sink in some embodiments. The heat sink may have a finned configuration to increase surface area and thereby remove heat more efficiently. The heat sink may also have cooling water or refrigerant flowing through it to improve heat removal efficiency. In some embodiments, the heat sink may be directly coupled to the cell through suitable thermal bonding material. In some embodiments, the heat sink may be coupled to a case enclosing the semiconductor package through thermal bonding material.

Although the foregoing embodiments of the invention have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within the scope and equivalents of the appended claims. In the claims, elements and/or steps do not imply any particular order of operation, unless explicitly stated in the claims.

What is claimed is:

1. A self-cooling semiconductor device, comprising:
a semiconductor substrate comprising a plurality of transistors;
a first electrically conductive plate thermally bonded to the semiconductor substrate;
a second electrically conductive plate; and
a semiconductor material located between the first electrically conductive plate and the second electrically conductive plate;
a first electrical lead from the first electrically conductive plate coupled to a semiconductor junction of the semiconductor substrate; and
a second electrical lead from the second electrically conductive plate coupled to a supply voltage, wherein the first electrical lead and the second electrical lead are coupled in series.

2. The self-cooling semiconductor device of claim 1, wherein a current is driven from the second electrically conductive plate to the first electrically conductive plate, thereby causing a thermal gradient between the first electrically conductive plate and the second electrically conductive plate.

3. The self-cooling semiconductor device of claim 1, wherein a thermal gradient is formed between the first electrically conductive plate and the second electrically conductive plate.

4. The self-cooling semiconductor device of claim 1, wherein the supply voltage powers the semiconductor device.

5. The self-cooling semiconductor device of claim 1, wherein the semiconductor material is one of silicon or germanium.

6. The self-cooling semiconductor device of claim 1, wherein the first electrically conductive plate and the second electrically conductive plate comprise a metal.

7. The self-cooling semiconductor device of claim 1, wherein a heat sink is coupled to the second electrically conductive plate.

8. The self-cooling semiconductor device of claim 1, wherein a temperature of the first thermally conductive plate is less than a temperature of the second thermally conductive plate in response to the supply voltage being applied to the semiconductor device.

9. The self-cooling semiconductor device of claim 1, wherein the first electrically conductive plate comprises a first metal and the second electrically conductive plate comprises a second metal, wherein the first metal is different than the second metal.

10. A self-cooling semiconductor package, comprising:
an integrated circuit incorporated into the semiconductor package;
a first electrically conductive plate thermally bonded to the semiconductor package;
a semiconductor material coupled to the first electrically conductive plate;
a second electrically conductive plate coupled to the semiconductor material;
a supply voltage coupled to the second electrically conductive plate; and
an electrical lead coupling the first electrically conductive plate to the integrated circuit, wherein the supply voltage and the electrical lead are coupled in series.

11. The self-cooling semiconductor package of claim 10, further comprising:
a case enclosing the semiconductor package, the first electrically conductive plate, the semiconductor material, and the second electrically conductive plate.

12. The self-cooling semiconductor package of claim 11, further comprising:
a heat sink coupled to one of the second electrically conductive plate or the case.

13. The self-cooling semiconductor package of claim 10, wherein the supply voltage provides a current in series to the semiconductor circuit package and to the second electrically conductive plate.

14. The self-cooling semiconductor package of claim 10, wherein the supply voltage powers the integrated circuit.

15. The self-cooling semiconductor package of claim 10, wherein the first electrically conductive plate and the second electrically conductive plate each comprise a metal.

16. The self-cooling semiconductor package of claim 10, wherein the semiconductor material comprises one of silicon or germanium.

17. A method of self-cooling a semiconductor package, comprising:
coupling a thermal gradient cell to an integrated circuit of the semiconductor package;
supplying a voltage to the thermal gradient cell; and
powering the integrated circuit with the voltage from the thermal gradient cell.

18. The method of claim 17, wherein the thermal gradient cell and the integrated circuit are coupled in series with a source supplying the voltage.

19. The method of claim 17, further comprising:
removing heat from the semiconductor package via a heat sink coupled to the thermal gradient cell.

20. The method of claim 17, wherein the thermal gradient cell comprises a first electrically conductive plate coupled to a second electrically conductive plate through a semiconductor material, wherein the first electrically conductive plate is coupled to the integrated circuit and the second electrically conductive plate is coupled to the voltage.
